(19) United States
(12) Patent Application Publication
(10) Pub. No.: US 2026/0333580 A1
(43) Pub. Date: Oct. 22, 2026

(54) ELECTRONIC ASSEMBLY AND PRINTED CIRCUIT BOARD

(71) Applicant: VIA Technologies, Inc., New Taipei City (TW)

(72) Inventors: Nai-Shung Chang, New Taipei City (TW); Chang-Li Tan, New Taipei City (TW); Chun-Yen Kang, New Taipei City (TW); Yun-Han Chen, New Taipei City (TW)

(73) Assignee: VIA Technologies, Inc., New Taipei City (TW)

(21) Appl. No.: 19/383,774

(22) Filed: Nov. 10, 2025

Related U.S. Application Data
(60) Provisional application No. 63/790,672, filed on Apr. 17, 2025.

(30) Foreign Application Priority Data
Sep. 11, 2025 (TW) 114134871

(51) Int. Cl. H05K 1/11; H05K 1/02

(52) U.S. Cl. CPC H05K 1/112; H05K 1/0251; H05K 1/115; H05K 2201/094; H05K 2201/09427

(57) ABSTRACT

An electronic assembly includes a printed circuit board (PCB) having a first surface, a second surface opposite to the first surface, a plurality of first conductive pads arranged on the first surface, a plurality of second conductive pads arranged on the second surface, and a plurality of conductive vias disposed in the PCB. The first conductive pads include a first ground pad and at least one first signal pad at a side of the first ground pad. The conductive vias include a conductive ground via and at least one conductive signal via. The at least one conductive ground via connected to the first ground pad is offset from directly below the first ground pad toward the at least one conductive signal via connected to the at least one first signal pad. No conductive ground via is connected directly below the first ground pad.

### CROSS-REFERENCE TO RELATED APPLICATION

This application claims the priority benefit of U.S. Provisional Application No. 63/790,672, filed on Apr. 17, 2025 and Taiwan Application No. 114134871, filed on Sep. 11, 2025. The entirety of each of the above-mentioned patent applications is hereby incorporated by reference herein and made a part of this specification.

### BACKGROUND OF THE INVENTION

### Field of the Invention

The invention relates to an electronic assembly, and more particularly to an electronic assembly in which a printed circuit board is used for mounting an electronic package.

### Description of Related Art

A printed circuit board (PCB) is a common platform for mounting electronic elements. The electronic elements mounted on the PCB may be electrically connected to each other through conductive vias (vertical electrical media) and conductive wires (horizontal electrical media) within the PCB. The layout of the conductive vias and the conductive wires significantly impacts the signal transmission quality between the electronic elements.

### SUMMARY OF THE INVENTION

The invention provides an electronic assembly, wherein the printed circuit board thereof is beneficial to improving the signal transmission quality between electronic elements.

An electronic assembly of the invention includes a printed circuit board, a first electronic package, and a second electronic package. The printed circuit board has a first surface, a second surface opposite to the first surface, a plurality of first conductive pads, a plurality of second conductive pads, and a plurality of conductive vias. The first conductive pads are arranged in area array on the first surface. The second conductive pads are arranged in area array on the second surface. The conductive vias are disposed on the printed circuit board. The first conductive pads include a first ground pad and at least one first signal pad. The at least one first signal pad is arranged at a side of the first ground pad. The conductive vias include at least one conductive ground via and at least one conductive signal via. The at least one conductive ground via connected to the first ground pad is offset from directly below the first ground pad toward the at least one conductive signal via connected to the at least one first signal pad. No conductive ground via is connected directly below the first ground pad. The first electronic package is mounted to the first surface of the printed circuit board and electrically connected to the first conductive pads of the first surface of the printed circuit board. The second electronic package is mounted to the second surface of the printed circuit board and electrically connected to the second conductive pads of the second surface of the printed circuit board.

A printed circuit board of the invention has a first surface and a second surface opposite to the first surface. The printed circuit board includes a plurality of first conductive pads and a plurality of conductive vias. The first conductive pads are arranged in area array on the first surface. The first conductive pads include a first ground pad and at least one first signal pad. The at least one first signal pad is arranged at a side of the first ground pad. The conductive vias are disposed in the printed circuit board. The conductive vias include at least one conductive ground via and at least one conductive signal via. The at least one conductive ground via connected to the first ground pad is offset from directly below the first ground pad toward the at least one conductive signal via connected to the at least one first signal pad. No conductive ground via is connected directly below the first ground pad.

Based on the above, in the invention, the conductive vias connected to the ground pads are offset from directly below the ground pads toward the conductive vias connected to the signal pads for signal isolation, which improves the quality of signal transmission.

### BRIEF DESCRIPTION OF THE DRAWINGS

FIG. 1A is a schematic diagram of an electronic assembly of an embodiment of the invention.

FIG. 1B is a partially enlarged view of FIG. 1A.

FIG. 2A is a partially enlarged top view of the printed circuit board of FIG. 1A.

FIG. 2B is a cross-sectional view of FIG. 2A along the cutting line 2C- 2C’.

FIG. 2C is a partially enlarged view of FIG. 2A.

FIG. 3 is a partially enlarged top view of a printed circuit board of another embodiment of the invention.

FIG. 4 is a partially enlarged top view of a printed circuit board of another embodiment of the invention.

FIG. 5 is a partially enlarged top view of a printed circuit board of another embodiment of the invention.

### DESCRIPTION OF THE EMBODIMENTS

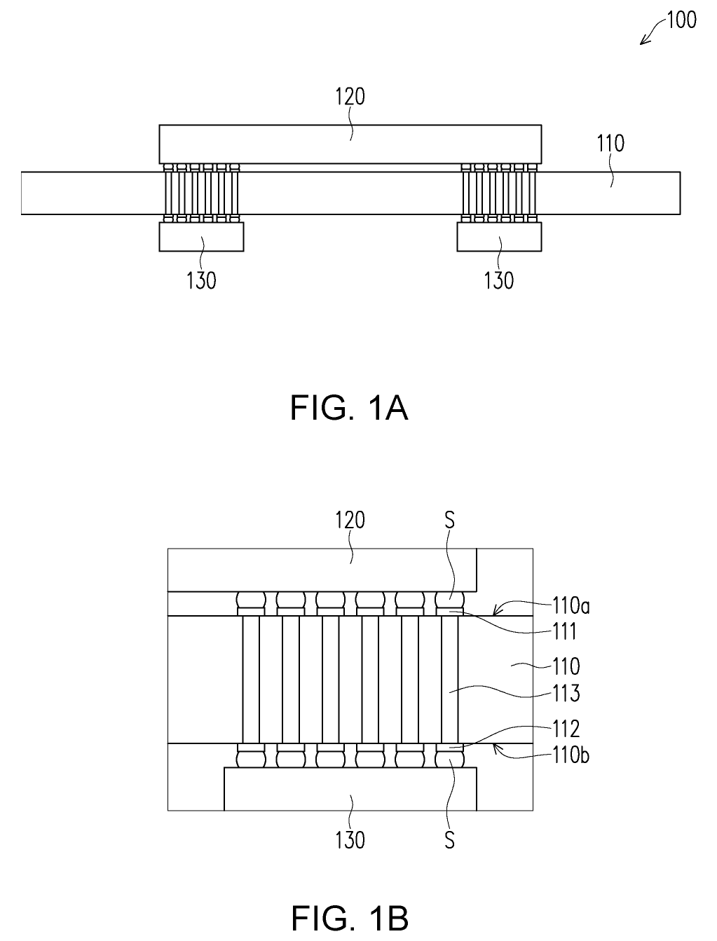

Referring to FIGS. 1A and 1B , in the present embodiment, an electronic assembly 100 includes a printed circuit board 110. The printed circuit board 110 has a first surface 110a, a second surface 110b opposite to the first surface 110a, a plurality of first conductive pads 111, a plurality of second conductive pads 112, and a plurality of conductive vias 113. The first conductive pads 111 are arranged in area array on the first surface 110a. The second conductive pads 112 are arranged in area array on the second surface 110b. The conductive vias 113 are disposed in the printed circuit board 110.

In the present embodiment, the electronic assembly 100 further includes a first electronic package 120 and one or a plurality of second electronic packages 130. The first electronic package 120 is mounted to the first surface 110a of the printed circuit board 110 and electrically connected to the first conductive pads 111 of the first surface 110a of the printed circuit board 110. The second electronic package 130 is mounted to the second surface 110b of the printed circuit board 110 and electrically connected to the second conductive pads 112 of the second surface 110b of the printed circuit board 110. For example, the first electronic package 120 may be mounted to the first conductive pads 111 of the first surface 110a of the printed circuit board 110 through solder balls S. The second electronic package 130 may be mounted to the second conductive pads 112 of the second surface 110b of the printed circuit board 110 through the solder balls S.

In the present embodiment, the orthographic projection of the first electronic package 120 on the first surface 110a and the orthographic projection of the second electronic package 130 on the first surface 110a may be overlapped with each other. Furthermore, the orthographic projection of the second electronic package 130 on the first surface 110a falls in the region of the orthographic projection of the first electronic package 120 on the first surface 110a. It means that the size of the second electronic package 130 is less than the size of the first electronic package 120. In an embodiment, in the case that there are a plurality of second electronic packages 130, the orthographic projection of each of the second electronic packages 130 on the first surface 110a falls in the region of the orthographic projection of the first electronic package 120 on the first surface 110a. Furthermore, the first electronic package 120 may be a larger-sized processor chip package, and the second electronic package 130 may be a smaller-sized memory chip package, but it is not limited thereto.

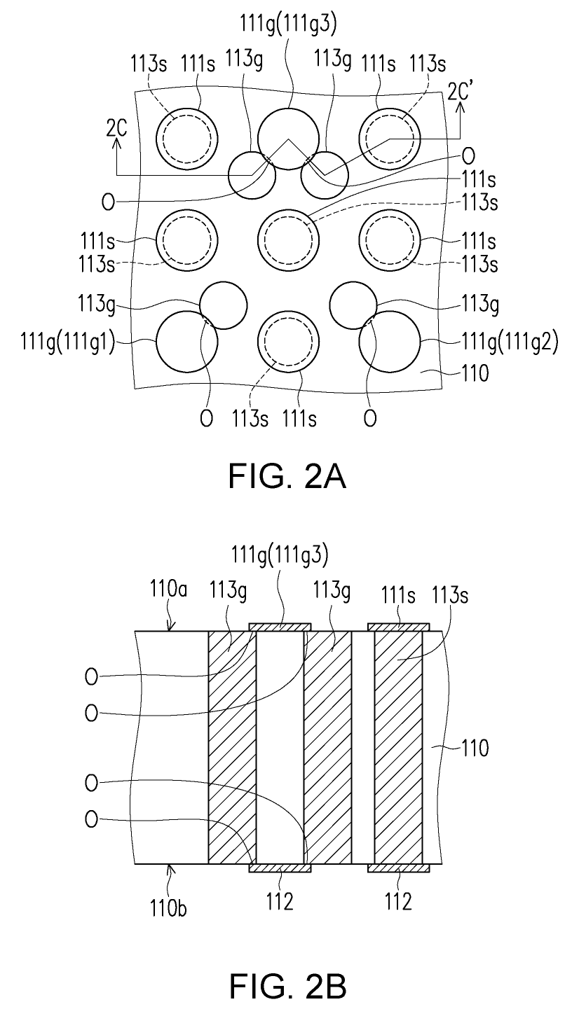

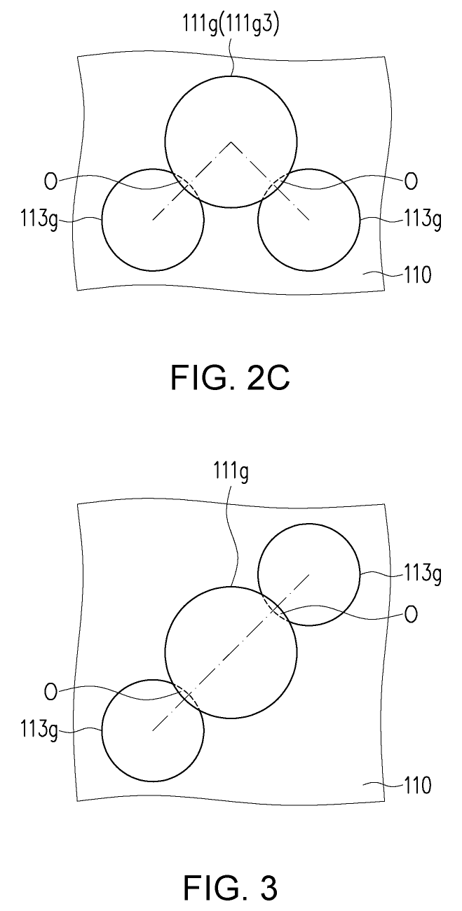

Referring to FIGS. 2A,2B and 2C, in the present embodiment, the first conductive pads 111 include one or a plurality of first ground pads 111g (111g1, 111g2, 111g3) and one or a plurality of first signal pads 111s. The conductive vias 113 include one or a plurality of conductive ground vias 113g and one or a plurality of conductive signal vias 113s. The first signal pads 111s are arranged at a side of the first ground pads 111g, and the first signal pads 111s and the adjacent first ground pads 111g are not connected to each other. The conductive ground vias 113g connected to the first ground pads 111g are offset from directly below the first ground pads 111g toward the least one conductive signal via 113s. The conductive signal via 113s is connected to the least one first signal pad 111s, and the conductive signal via 113s and the adjacent conductive ground via 113g are not connected to each other. The orthographic projection of the conductive ground via 113g connected to the first ground pads 111g and the that of the first ground pads 111g on the first surface 110a may be partially overlapped in an overlapping region O. The ratio of the area of the overlapping region O to the area of the orthographic projection of the first ground pads 111g on the first surface 110a is greater than 0% and less than or equal to 10%. It should be noted that in the present embodiment, the conductive ground vias 113g are disposed in an offset manner toward the conductive signal vias 113s of the first signal pads 111s, and no conductive ground via 113g is connected directly below the first ground pads 111g. However, current common practice is to dispose the conductive ground vias 113g directly below the first ground pads 111g (similar to the arrangement of the first signal pads 111s and the conductive signal vias 113s of FIG. 2B). Therefore, currently, the distance between conventional conductive signal vias 113s and conductive ground vias 113g is typically longer, so it would result in poor signal isolation. However, in the present embodiment, the distance between the conductive signal vias 113s and the offset conductive ground vias 113g is shorter, providing a better signal return path and enhancing signal isolation, thereby improving the quality of signal transmission. Furthermore, the phrase “no conductive ground via 113g directly below the first ground pads 111g” means no conductive ground via 113g is in the region of the printed circuit board 110 between the first ground pads 111g of the first surface 110a and the corresponding second conductive pads 112 of the second surface 110b. Moreover, the phrase “the conductive signal vias 113s located directly below the first signal pads 111s” in FIG. 2B means that the orthographic projection of the conductive signal vias 113s on the first surface 110a falls in the region of the orthographic projection of the first signal pads 111s on the first surface 110a.

Referring to FIG. 2B, the conductive ground vias 113g pass through the printed circuit board 110 and are connected to the corresponding second conductive pads 112. The orthographic projection of the conductive ground vias 113g and the that of the corresponding second conductive pads 112 on the second surface 110b may be partially overlapped in an overlapping region O. The ratio of the overlapping area to the area of the orthographic projection of the corresponding second conductive pads 112 on the second surface 110b is greater than 0% and less than or equal to 10%. Furthermore, for the second electronic package 130, the arrangement of the second conductive pads 112 connected to the conductive ground vias 113g is the same as the arrangement of the first ground pads 111g connected to the conductive ground vias 113g.

Referring to FIG. 2A, in the present embodiment, the conductive ground via 113g connected to the first ground pads 111g1 or 111g2 (i.e., the first ground pad 111g1 at the lower left corner or the first ground pad 111g2 at the lower right corner of FIG. 2A) may be offset toward the conductive signal vias 113s (two or three conductive signal vias 113s) at a neighboring region thereof, wherein the conductive signal vias 113s are connected to the corresponding first signal pads 111s. Furthermore, the two conductive ground vias 113g connected to the first ground pad 111g3 (i.e., the first ground pad 111g3 at the upper center of FIG. 2A) may be respectively offset toward the conductive signal vias 113s (two or three conductive signal vias 113s) at a neighboring region thereof, and the conductive signal vias 113s are connected to the corresponding first signal pads 111s.

Referring to FIG. 2C, in the present embodiment, the number of the conductive ground vias 113g connected to the first ground pads 111g may be two. The orthographic projection of the conductive ground vias 113g on the first surface 110a and the orthographic projection of the first ground pad 111g to which the conductive ground vias 113g are connected on the first surface 110a may be arranged in a substantially L-shape. The substantially L-shape arrangement of the orthographic projections is from connecting lines of the center point of the orthographic projection of the first ground pad 111g and the center point of the orthographic projection of the conductive ground vias 113g.

Referring to FIG. 3, in the present embodiment, the number of the conductive ground vias 113g connected to the first ground pad 111g may be two. The orthographic projection of the conductive ground vias 113g on the first surface 110a and the orthographic projection of the first ground pad 111g to which the conductive ground vias 113g are connected on the first surface 110a may be arranged in a substantially straight line. The substantially straight line arrangement of the orthographic projections is from a connecting line of the center point of the orthographic projection of the first ground pad 111g and the center point of the orthographic projection of the conductive ground vias 113g.

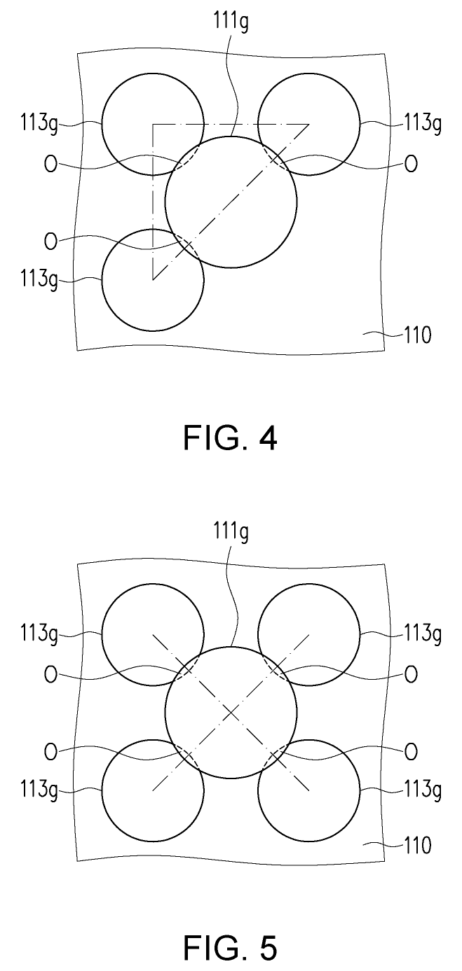

Referring to FIG. 4, the number of the conductive ground vias 113g connected to the first ground pad 111g may be three. The orthographic projection of the conductive ground vias 113g on the first surface 110a and the orthographic projection of the first ground pad 111g to which the conductive ground vias 113g are connected may be arranged in a substantially triangular arrangement. The substantially triangular arrangement of the orthographic projections is from a connecting line of the center point of the orthographic projection of the first ground pad 111g and the center point of the orthographic projection of the conductive ground vias 113g, and connecting lines of the center points of the orthographic projections of two adjacent conductive ground vias 113g.

Referring to FIG. 5, the number of the conductive ground vias 113g connected to the first ground pad 111g may be four. The orthographic projection of the conductive ground vias 113g on the first surface 110a and the orthographic projection of the first ground pad 111g to which the conductive ground vias 113g are connected on the first surface 110a may be arranged in a substantially X-shape. The substantially X-shape arrangement of the orthographic projections is from connecting lines of the center point of the orthographic projection of the first ground pad 111g and the center point of the orthographic projection of the conductive ground vias 113g.

Based on the above, in the invention, the conductive vias connected to the ground pads are offset from directly below the ground pads toward the conductive vias connected to the signal pads for signal isolation, which improves the quality of signal transmission.

What is claimed is:

1. An electronic assembly, comprising:
a printed circuit board having a first surface, a second surface opposite to the first surface, a plurality of first conductive pads, a plurality of second conductive pads, and a plurality of conductive vias, wherein the first conductive pads are arranged in area array on the first surface, the second conductive pads are arranged in area array on the second surface, the conductive vias are disposed in the printed circuit board, the first conductive pads comprise a first ground pad and at least one first signal pad, the at least one first signal pad is arranged at a side of the first ground pad, the conductive vias comprise at least one conductive ground via and at least one conductive signal via, the at least one conductive ground via connected to the first ground pad is offset from directly below the first ground pad toward the at least one conductive signal via connected to the at least one first signal pad, and no conductive ground via is connected directly below the first ground pad;
a first electronic package mounted to the first surface of the printed circuit board and electrically connected to the first conductive pads of the first surface of the printed circuit board; and
a second electronic package mounted to the second surface of the printed circuit board and electrically connected to the second conductive pads of the second surface of the printed circuit board.

2. The electronic assembly of claim 1, wherein an orthographic projection of the at least one conductive ground via connected to the first ground pad and an orthographic projection of the first ground pad on the first surface partially overlap in an overlapping region.

3. The electronic assembly of claim 2, wherein a ratio of the area of the overlapping region to the area of the orthographic projection of the first ground pad on the first surface is greater than 0% and less than or equal to 10%.

4. The electronic assembly of claim 1, wherein the at least one conductive ground via passes through the printed circuit board and is connected to the corresponding second conductive pad, an orthographic projection of the at least one conductive ground via and an orthographic projection of the corresponding second conductive pad on the second surface partially overlap in an overlapping region, and an arrangement method of the second conductive pad connected to the at least one conductive ground via is the same as an arrangement method of the first ground pad connected to the at least one conductive ground via.

5. The electronic assembly of claim 4, wherein a ratio of the area of the overlapping region to the area of the orthographic projection of the corresponding second conductive pad on the second surface is greater than 0% and less than or equal to 10%.

6. The electronic assembly of claim 1, wherein a number of the at least one first signal pad is a plurality, and the at least one conductive ground via connected to the first ground pad is offset toward the at least one conductive signal via connected to the first signal pads.

7. The electronic assembly of claim 1, wherein a number of the at least one conductive ground via connected to the first ground pad is two, and an orthographic projection of the conductive ground vias on the first surface and an orthographic projection of the first ground pad to which the conductive ground vias are connected on the first surface are arranged in an L-shape or a straight line.

8. The electronic assembly of claim 1, wherein a number of the at least one conductive ground via connected to the first ground pad is three, and an orthographic projection of the conductive ground vias on the first surface and an orthographic projection of the first ground pad to which the conductive ground vias are connected on the first surface are arranged in a triangle.

9. The electronic assembly of claim 1, wherein a number of the at least one conductive ground via connected to the first ground pad is four, and an orthographic projection of the conductive ground vias on the first surface and an orthographic projection of the first ground pad to which the conductive ground vias are connected on the first surface are arranged in an X-shape.

10. The electronic assembly of claim 1, wherein an orthographic projection of the second electronic package on the first surface and an orthographic projection of the first electronic package on the first surface are overlapped with each other.

11. The electronic assembly of claim 10, wherein a size of the second electronic package is less than a size of the first electronic package.

12. A printed circuit board, having a first surface and a second surface opposite to the first surface, the printed circuit board comprising:
a plurality of first conductive pads arranged in area array on the first surface, wherein the first conductive pads comprise a first ground pad and at least one first signal pad, and the at least one first signal pad is arranged at a side of the first ground pad; and
a plurality of conductive vias disposed in the printed circuit board, wherein the conductive vias comprise at least one conductive ground via and at least one conductive signal via, the at least one conductive ground via connected to the first ground pad is offset from directly below the first ground pad toward the at least one conductive signal via connected to the at least one first signal pad, and no conductive ground via is connected directly below the first ground pad.

13. The printed circuit board of claim 12, wherein an orthographic projection of the at least one conductive ground via connected to the first ground pad and an orthographic projection of the first ground pad on the first surface partially overlap in an overlapping region.

14. The printed circuit board of claim 13, wherein a ratio of the area of the overlapping region to the area of the orthographic projection of the first ground pad on the first surface is greater than 0% and less than or equal to 10%.

15. The printed circuit board of claim 12, further comprising:
a plurality of second conductive pads arranged in area array on the second surface, wherein the at least one conductive ground via passes through the printed circuit board and is connected to the corresponding second conductive pad, an orthographic projection of the at least one conductive ground via and an orthographic projection of the corresponding second conductive pad on the second surface partially overlap in an overlapping region, and an arrangement method of the second conductive pad connected to the at least one conductive ground via is the same as an arrangement method of the first ground pad connected to the at least one conductive ground via.

16. The printed circuit board of claim 15, wherein a ratio of the area of the overlapping region to the area of the orthographic projection of the corresponding second conductive pad on the second surface is greater than 0% and less than or equal to 10%.

17. The printed circuit board of claim 12, wherein a number of the at least one first signal pad is a plurality, and the at least one conductive ground via connected to the first ground pad is offset toward the conductive vias connected to the first signal pads.

18. The printed circuit board of claim 12, wherein a number of the at least one conductive ground via connected to the first ground pad is two, and an orthographic projection of the conductive ground vias on the first surface and an orthographic projection of the first ground pad to which the conductive ground vias are connected on the first surface are arranged in an L-shape or a straight line.

19. The printed circuit board of claim 12, wherein a number of the at least one conductive ground via connected to the first ground pad is three, and an orthographic projection of the conductive ground vias on the first surface and an orthographic projection of the first ground pad to which the conductive ground vias are connected on the first surface are arranged in a triangle.

20. The printed circuit board of claim 12, wherein a number of the at least one conductive ground via connected to the first ground pad is four, and an orthographic projection of the conductive ground vias on the first surface and an orthographic projection of the first ground pad to which the conductive ground vias are connected on the first surface are arranged in an X-shape.
